(19) United States
(12) Patent Application Publication
(10) Pub. No.: US 2014/0201991 A1
(43) Pub. Date: Jul. 24, 2014

(54) METHOD FOR CONNECTING PLATES OF A SUBSTRATE DEVICE

(71) Applicants: Cheih Oh Yang, (US); Wei Ou Yang, (US); JIANGSU SUN & MOON LIGHTING CO., LTD., Yancheng City (CN)

(72) Inventors: CHIEH OU YANG, New Taipei City (TW); WEI OU YANG, Taipei City (TW)

(73) Assignees: Cheih Oh Yang, New Taipei City (TW); Jiangsu Sun & Moon Lighting Co., Ltd., Yancheng City (CN); Wei Ou Yang, Taipei City (TW)

(21) Appl. No.: 13/846,927

(22) Filed: Mar. 18, 2013

(30) Foreign Application Priority Data
Jan. 24, 2013 (CN) 201320038182.2
Mar. 7, 2013 (TW) 102107961

(51) Int. Cl. H05K 3/30

(52) U.S. Cl. CPC H05K 3/30
USPC 29/840

(57) ABSTRACT

An approach is provided for a method for connecting multiple plates of a substrate device, the substrate device at least comprises a conductive layer and a plate has at least one hollowed hole that is used to directly transfer the heat from a high power electrical chip to the conductive layer, the method comprises acts of forming a first cupper layer on a top surface of the plate and forming a second cupper layer on a bottom surface of the plate, printing a circuit on the first cupper layer, and soldering the second cupper layer on the conductive layer with a soldering paste.

### FIELD OF THE INVENTION

Embodiments of the present invention relate to a heat consumption and insulation application of a high power electrical chip, particular to a method for connecting multiple plates of a substrate device to increase the life cycle of the high power electrical chip.

### BACKGROUND

With reference to FIGS. 1A to 1D, a substrate comprises a FR4 glass fiber plate or a FPC plate (i.e. a foldable print circuit board or a soft plate) 11 and a vapor chamber 12. The FR4 glass fiber plate or the FPC plate 11 connects to the vapor chamber 12 by a glue. However, the glue may be overflowed due to the FR4 glass fiber plate or the FPC plate 11 has multiple hollowed holes 111 to increase heat consumption efficiency of a high power electrical chip 13 and the overflowed glue will pollute a solder plate of the high power electrical chip 13, so that a precisely operation to plate the glue is necessary. On the other hand, because the high power electrical chip 13 keeps heating, the glue will lose the adhesive capability and the FR4 glass fiber plate or the FPC plate 11 departed from the vapor chamber 12 under a repeatedly heating and cooling environment. The FR4 glass fiber plate or the FPC plate 11 has been departed from the vapor chamber 12 and damages the high power electrical chip 13.

With reference to FIGS. 2A to 2D, a circuited layer 21 is printed on a vapor chamber 22 to prevent the FR4 glass fiber plate or the FPC plate departing from the vapor chamber 22 and the high power electrical chip damaging due to above-mentioned problem. However, when the vapor chamber is provided to a client in the middle eastern countries, the vapor chamber might be complained and asked for further maintenance due to the departed off of a black glue of the vapor chamber. The black glue's departing is resulted from an epoxy resin comprised a polystyrene acrylic and used to fasten a conductive wire and a soldering plate 23 is weaken due to the temperature changes. Therefore, the soldering plate 23 is pulled out and is departed from the vapor chamber that reduces the life cycle of the substrate device.

Accordingly, the inventors of the present invention work hard to figure out a method to solve the above-mentioned problem.

### Some Exemplary Embodiments

These and other needs are addressed by the present invention, wherein an approach is provided for a method for connecting multiple plates of a substrate device to increase the life cycle of the high power electrical chip.

According to one aspect of an embodiment of the present invention, a method for connecting multiple plates of a substrate device, the substrate device at least comprises a conductive layer and a plate has at least one hollowed hole that is used to directly transfer the heat from a high power electrical chip to the conductive layer, the method comprises acts of forming a first cupper layer on a top surface of the plate and forming a second cupper layer on a bottom surface of the plate, printing a circuit on the first cupper layer, and soldering the second cupper layer on the conductive layer with a soldering paste.

### BRIEF DESCRIPTION OF THE DRAWINGS

The invention is illustrated by way of example, and not by way of limitation, in the figures of the accompanying drawings in which like reference numerals refer to similar elements and in which:

FIG. 1A is a respective view of a conventional FR4 fiber plate or a FPC plate;

FIG. 1B is a respective view of a conventional vapor chamber;

FIG. 1C is a respective view showing an assembly connecting the conventional FR4 fiber plate or a FPC plate with the conventional vapor chamber by a glue;

FIG. 1D is a respective view showing a light emitting diode chip is mounted on the assembly in FIG. 1C;

FIG. 2A is a respective view of a vapor chamber printed with a circuit in accordance with the present invention;

FIG. 2B is a cross sectioned view of FIG. 2A;

FIG. 2C is a respective view showing a light emitting diode chip is mounted on vapor chamber in FIG. 2A;

FIG. 2D is a cross sectioned view of FIG. 2C;

FIG. 3 is a respective view of a substrate in accordance with the present invention;

FIG. 3A is a cross sectioned view of FIG. 3;

FIG. 4 is a respective view showing a light emitting diode chip is mounted on the substrate in FIG. 3; and

FIG. 4A is a cross sectioned view showing a FR4 fiber plate or a FPC plate of the substrate in accordance with the present invention.

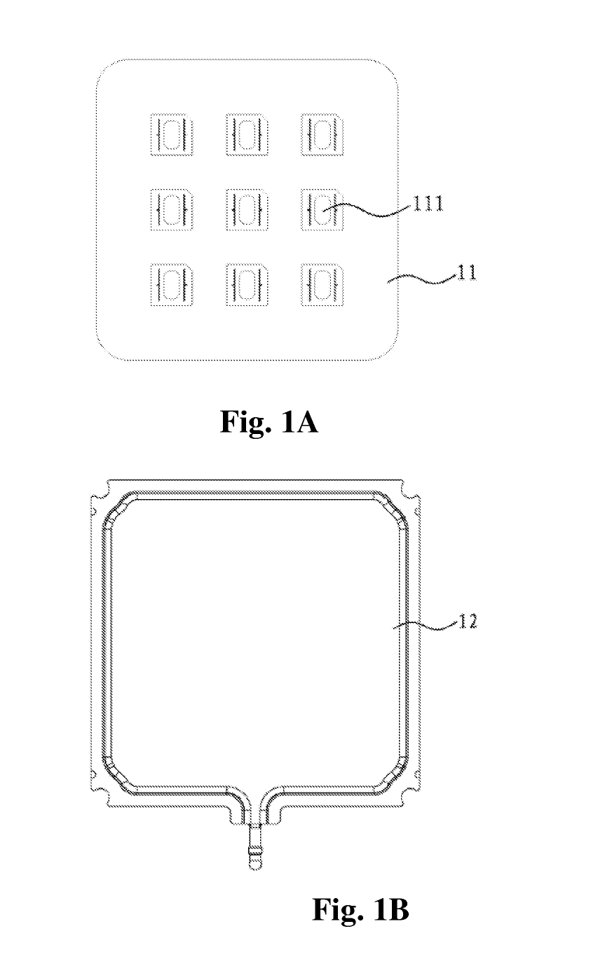

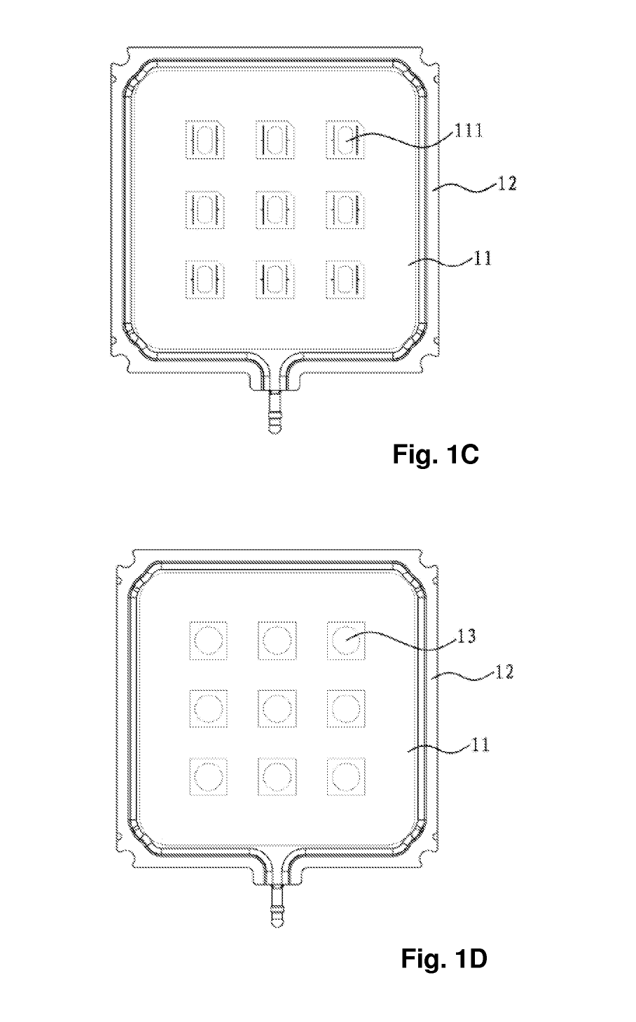

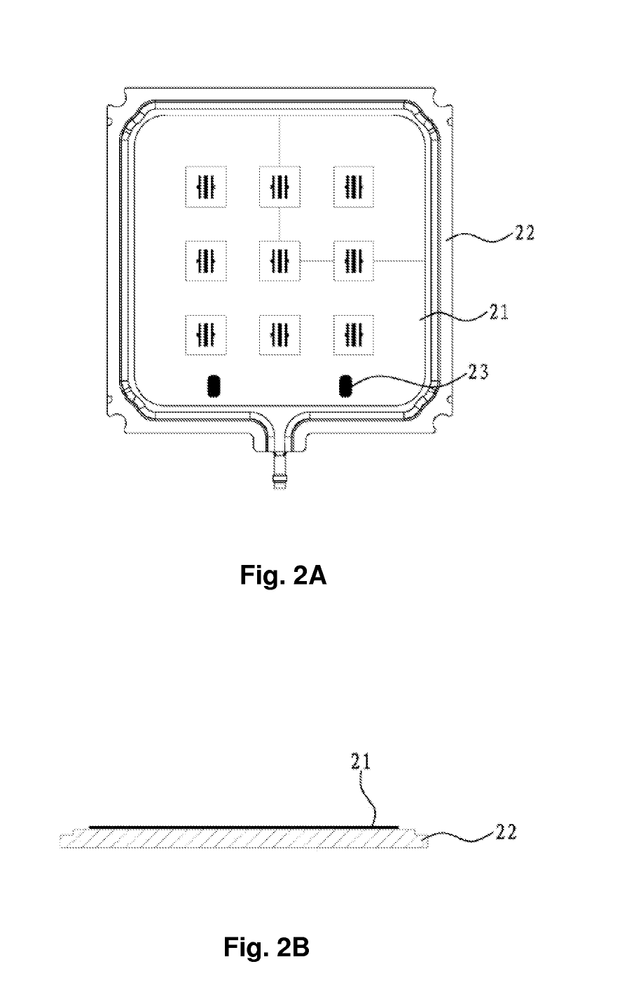

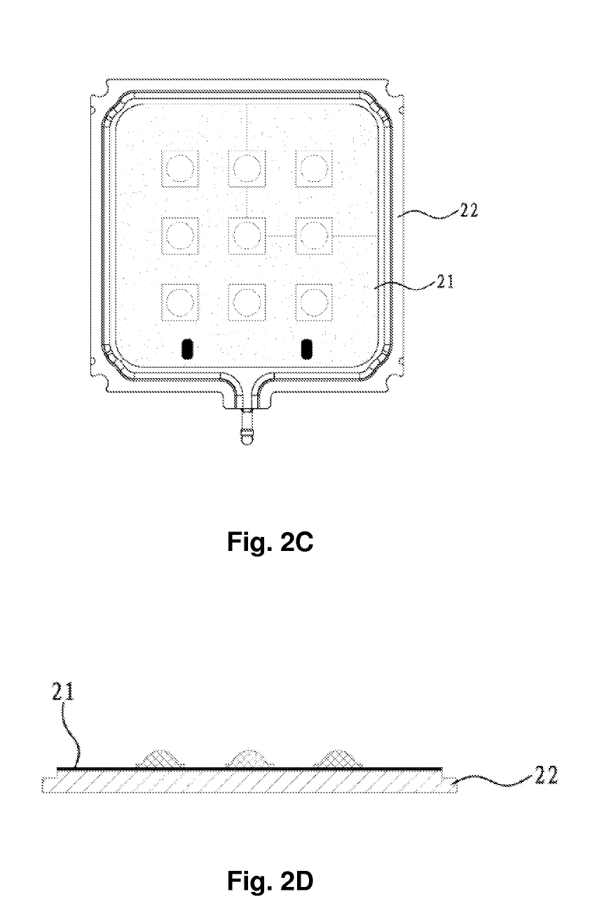

### DESCRIPTION OF THE PREFERRED EMBODIMENT

A method for connecting multiple plates of a substrate device is disclosed. In the following description, for the purposes of explanation, numerous specific details are set forth in order to provide a thorough understanding of the present invention. It is apparent, however, to one skilled in the art that the invention may be practiced without specific details or with an equivalent arrangement. In other instances, well-known structures and devices are shown in block diagram form in order to avoid unnecessarily obscuring the embodiments of the present invention.

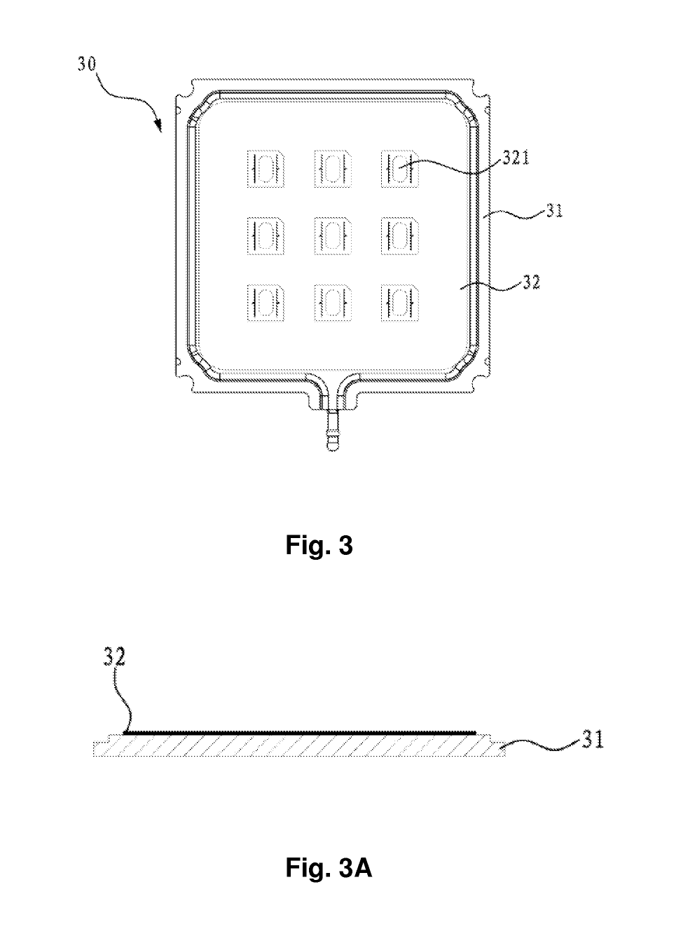

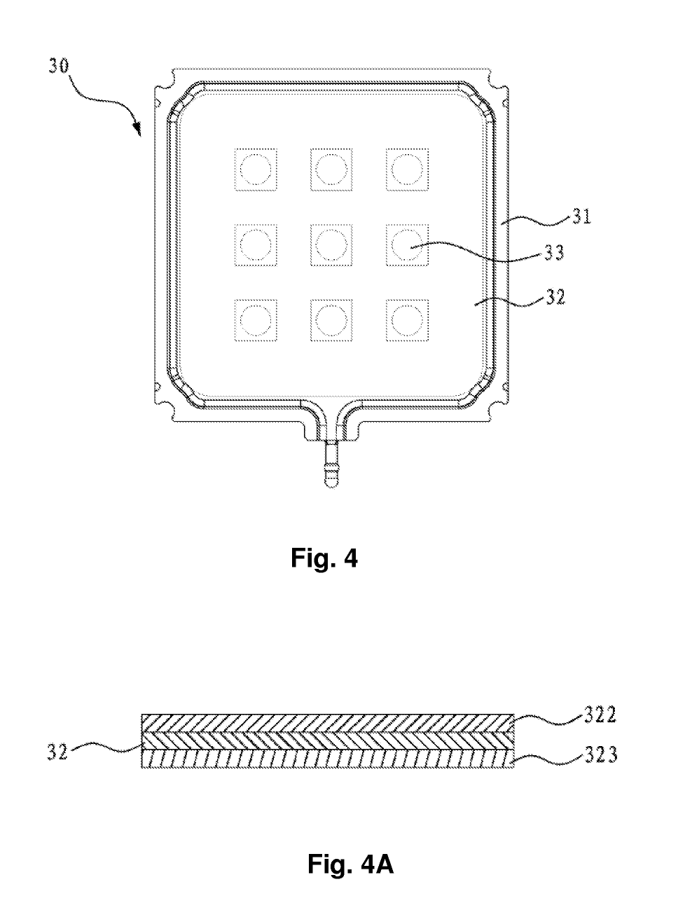

With reference to FIGS. 3 and 3A, a substrate device 30 in accordance with the present invention comprises a conductive layer 31 and a plate 32, such as a FR4 glass fiber plate or the FPC plate. The plate 32 comprises at least one hollowed hole 321 for a high power electrical chip, such as an LED chip 33, directly connecting with the conductive layer 31 to quickly transfer the heat generated from the LED chip 33 to the conductive layer 31. In this embodiment, the conductive layer 31 is a vapor chamber and is made of an alumina substrate or a cupper substrate.

It is noted that, in this embodiment, the FR4 glass fiber plate or the FPC plate 32 further comprises a first cupper layer 322 and a second cupper layer 323. The first cupper layer 322 is coated on a top surface of the plate 32 and is printed with a circuit. The second cupper layer 323 is coated on a bottom surface of the plate 32 and is connected to the conductive layer 31, specifically, the second cupper layer 323 is soldered to the conductive layer 31 by a solder paste with an infrared reflow soldering process.

Accordingly, the substrate device 30 of the present invention directly solders the second cupper layer 323 of the plate 32 on the conductive layer 31 to avoid the plate 32 departing from the conductive layer 32 or the LED chip 33 damaging due to repeatedly heating and cooling of the glue. Also, the plate (the FR4 glass fiber plate or the FPC plate) 32 has characteristic of highly peel resistance to reduce a solder plate peeled off from the plate 32 and to increase the life cycle of the substrate device 30.

Furthermore, the plate (the FR4 glass fiber plate or the FPC plate) 32 has two cupper layers disposed on the both surfaces to increase the operation convenience. The second cupper layer 323 is used to be the soldering layer to overcome the soldering problem existed in the conventional process and to change the prejudice that the second cupper layer 323 is only to be a circuit printed layer. The conventional way is to remove the other cupper layer when there is only one layer is needed.

While the invention has been described in connection with a number of embodiments and implementations, the invention is not so limited but covers various obvious modifications and equivalent arrangements, which fall within the purview of the appended claims. Although features of the invention are expressed in certain combinations among the claims, it is contemplated that these features can be arranged in any combination and order.

What is claimed is:

1. A method for connecting multiple plates of a substrate device, the substrate device at least comprises a conductive layer and a plate has at least one hollowed hole that is used to directly transfer the heat from a high power electrical chip to the conductive layer, the method comprising:
forming a first cupper layer on a top surface of the plate and forming a second cupper layer on a bottom surface of the plate;
printing a circuit on the first cupper layer; and
soldering the second cupper layer on the conductive layer with a soldering paste.

2. The method as claimed in claim 1, wherein the plate is a FR4 glass fiber plate or a FPC plate.

3. The method as claimed in claim 1, wherein the conductive layer is an alumina plate, a cupper plate or a vapor chamber.

4. The method as claimed in claim 1, wherein the high power electrical chip is a light emitting diode chip.

5. The method as claimed in claim 4, wherein the conductive layer is an alumina plate, a cupper plate or a vapor chamber.
